(19) United States
(12) Patent Application Publication
(10) Pub. No.: US 2020/0203932 A1
(43) Pub. Date: Jun. 25, 2020

(54) SEMICONDUCTOR LASER

(71) Applicant: SUMITOMO ELECTRIC INDUSTRIES, LTD., Osaka (JP)

(72) Inventor: Tsukuru KATSUYAMA, Osaka-shi (JP)

(73) Assignee: SUMITOMO ELECTRIC INDUSTRIES, LTD., Osaka (JP)

(21) Appl. No.: 16/690,871

(22) Filed: Nov. 21, 2019

(30) Foreign Application Priority Data
Dec. 19, 2018 (JP) 2018-237375

(51) Int. Cl. H01S 5/343; H01S 5/22

(52) U.S. Cl. CPC H01S 5/34313; H01S 5/2207

(57) ABSTRACT

A semiconductor laser includes an active layer which is provided between the p-type semiconductor region and the n-type semiconductor region and has a type II quantum well structure. The type II quantum well structure includes a well layer made of a III-V compound semiconductor and a plurality of barrier layers. The well layer includes a first region and a second region, the first region having a low potential for electrons in the well layer and a high potential for holes in the well layer, the second region having a high potential for electrons in the well layer and a low potential for holes in the well layer. The first region and the second region of the well layer are arranged in a direction from one of the barrier layers to another of the barrier layers.

### CROSS REFERENCE TO RELATED APPLICATIONS

The present application is based upon and claims the benefit of the priority from Japanese patent application No. 2018-237375, filed on Dec. 19, 2018, which is hereby incorporated by reference in its entirety.

### TECHNICAL FIELD

The present invention relates to a semiconductor laser.

### BACKGROUND

Document (“Novel type-II material system for laser applications in the near-infraredregime” C. Berger, C. Moller, P. Hens, C. Fuchs, W. Stolz, S. W. Koch, A. Ruiz Perez, J. Hader, and J. V. Moloney, AIP Advances 5, 047105 (2015)) discloses a laser diode including a W-shaped type II active layer.

### SUMMARY

The present disclosure provides a semiconductor laser, comprising: a p-type semiconductor region; an n-type semiconductor region; and an active layer which is provided between the p-type semiconductor region and the n-type semiconductor region, and has a type II quantum well structure, wherein the type II quantum well structure includes a well layer made of a III-V compound semiconductor and a plurality of barrier layers that provide respective barriers for electrons and holes in the well layer, wherein, in the type II quantum well structure, the well layer is provided between the barrier layers, wherein the well layer includes a first region and a second region, the first region having a low potential for electrons in the well layer and a high potential for holes in the well layer, the second region having a high potential for electrons in the well layer and a low potential for holes in the well layer, the high potential of the second region being higher than the low potential of the first region, the low potential of the second region being lower than the high potential of the first region, and wherein the first region and the second region of the well layer are arranged in a direction from one of the barrier layers to another of the barrier layers.

The present disclosure provides a semiconductor laser, comprising: a p-type semiconductor region; an n-type semiconductor region; and an active layer which is provided between the p-type semiconductor region and the n-type semiconductor region and has a type II quantum well structure, wherein the type II quantum well structure includes a plurality of well layers containing a III-V compound semiconductor, and a plurality of barrier layers that provide respective barriers for electrons and holes in each of the well layers, wherein the well layers and the barrier layers are alternately arranged so that each of the barrier layers is provided between the well layers, wherein each of the well layers includes at least one first region and at least one second region, wherein the at least one first region and the at least one second region of each of the well layers are alternately arranged in a direction from one of the barrier layers to another of the barrier layers, wherein each of the at least one first region forms a type II heterojunction with at least one of the at least one second region, and wherein at least one of the at least one first region and the at least one second region has a part containing a dopant.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 is a diagram showing a semiconductor laser according to the present embodiment.

FIG. 2 shows conduction band and valence band potentials in an active layer.

FIG. 3 is a diagram showing profiles of selectively added dopant in a type II quantum well structure.

FIG. 4 is a diagram showing profiles of indium and antimony in the type II quantum well structure.

### DETAILED DESCRIPTION

### Problem to be Solved by the Present Disclosure

A light source for light with a longer wavelength than a wavelength band that is mainly used for optical communication, for example, a 1.5 μm band, is required. A Group III-V material containing antimony as a Group V element is one candidate for a long-wavelength light source and can realize a heterojunction different from type I.

### Description of Embodiments of the Present Disclosure

Several specific examples will be described.

The semiconductor laser according to the specific example includes (a) a p-type semiconductor region, (b) an n-type semiconductor region, and (c) an active layer which is provided between the p-type semiconductor region and the n-type semiconductor region and has a type II quantum well structure. The type II quantum well structure includes a well layer made of a III-V compound semiconductor and a plurality of barrier layers that provide respective barriers for electrons and holes in the well layer. In the type II quantum well structure, the well layer is provided between the barrier layers, the well layer includes a first region and a second region. The first region has a low potential for electrons in the well layer and a high potential for holes in the well layer. The second region has a high potential for electrons in the well layer and a low potential for holes in the well layer. The high potential of the second region is higher than the low potential of the first region. The low potential of the second region is lower than the high potential of the first region. The first region and the second region of the well layer are arranged in a direction from one of the barrier layers to another of the barrier layers.

According to the semiconductor laser, the first region and the second region arranged in a direction from one of the barrier layers to another of the barrier layers are provided in the well layer. The first region provides a low potential for electrons in the well layer and provides a high potential for holes in the well layer. The second region provides a high potential for electrons in the well layer and provides a low potential for holes in the well layer.

The arrangement of the first region and the second region provides a large probability amplitude for electrons in the first region and provides a large probability amplitude for holes in the second region. The barrier layer shifts a wave function of electrons and/or a wave function of holes inward in the well layer including the first region and the second region.

In the semiconductor laser according to the specific example, the first region includes a first ITT-V compound semiconductor containing indium as a Group III element and containing arsenic as a Group V element, the first III-V compound semiconductor is a ternary compound or a quaternary compound, the second region includes a second III-V compound semiconductor containing gallium as a Group III element and containing antimony as a Group V element, and the second III-V compound semiconductor is a ternary compound or a quaternary compound.

According to the semiconductor laser, the ternary compound and the quaternary compound of the first III-V compound semiconductor and the ternary compound and the quaternary compound of the second III-V compound semiconductor enable emission of light with a long wavelength.

In the semiconductor laser according to the specific example, the first region includes one of GaInAs and GaInAsP, and the second region includes one of GaAsSb and GaInAsSb.

According to the semiconductor laser, these ternary compounds and quaternary compounds can provide a quantum level at which light can be emitted. The ternary compound and the quaternary compound can provide a type II band alignment for the well layer including the first region and the second region.

In the semiconductor laser according to the specific example, the first region has a part containing an n-type dopant.

According to the semiconductor laser, the first region containing an n-type dopant forms a deep well according to the concentration of the n-type dopant and forms a high potential according to the concentration of the n-type dopant. Addition of the n-type dopant causes a level difference for optical transition in the well layer to be shifted to a longer wavelength.

In the semiconductor laser according to the specific example, the second region has a part containing a p-type dopant.

According to the semiconductor laser, the second region containing a p-type dopant forms a high potential according to the concentration of the p-type dopant and forms a deep well according to the concentration of the p-type dopant. Addition of the p-type dopant causes a level difference for optical transition in the well layer to be shifted to a longer wavelength.

The semiconductor laser according to the specific example includes (a) a p-type semiconductor region, (b) an n-type semiconductor region, and (c) an active layer which is provided between the p-type semiconductor region and the n-type semiconductor region and has a type II quantum well structure. The type II quantum well structure includes a plurality of well layers containing a III-V compound semiconductor and a plurality of barrier layers that provide respective barriers for electrons and holes in each of the well layers. The well layers and the barrier layers are alternately arranged so that each of the barrier layers is provided between the well layers, each of the well layers includes at least one first region and at least one second region. The at least one first region and the at least one second region of each of the well layers are alternately arranged in a direction from one of the barrier layers to another of the barrier layers. Each of the at least one first region forms a type II heterojunction with at least one of the at least one second region. At least one of the at least one first region and the at least one second region has a part containing a dopant.

According to the semiconductor laser, at least one region of the first region and the second region has a part containing a dopant that can generate majority carrier in the region. Addition of the dopant causes the level difference for optical transition in the well layer to be shifted.

In addition, the well layers and the barrier layers may be alternately arranged so that each of the well layers is provided between the barrier layers.

In the semiconductor laser according to the specific example, the first region has a low potential for electrons in the well layer and has a high potential for holes in the well layer. The first region has a part containing an n-type dopant.

According to the semiconductor laser, the first region has an n-type dopant added thereto. Addition of the n-type dopant causes a level difference for optical transition in the well layer to be shifted to a longer wavelength.

In the semiconductor laser according to the specific example, the second region has a high potential for electrons in the well layer and has a low potential for holes in the well layer, and the second region has a part containing a p-type dopant.

According to the semiconductor laser, the second region has a p-type dopant added thereto. Addition of the p-type dopant causes a level difference for optical transition in the well layer to be shifted to a longer wavelength.

### Advantageous Effect of the Present Disclosure

As described above, according to one aspect of the present disclosure, it is possible to provide a semiconductor laser having a quantum well structure that enables emission of light with a long wavelength in a Group III-V material containing antimony as a Group V element.

### Detailed Description of the Embodiments of the Present Disclosure

The concept of the present invention can be easily understood in consideration of the following detailed description with reference to the exemplified appended diagrams. Next, with reference to the appended drawings, an embodiment related to a semiconductor light emitting device as a semiconductor laser will be described. The same parts are denoted with the same reference numerals if possible.

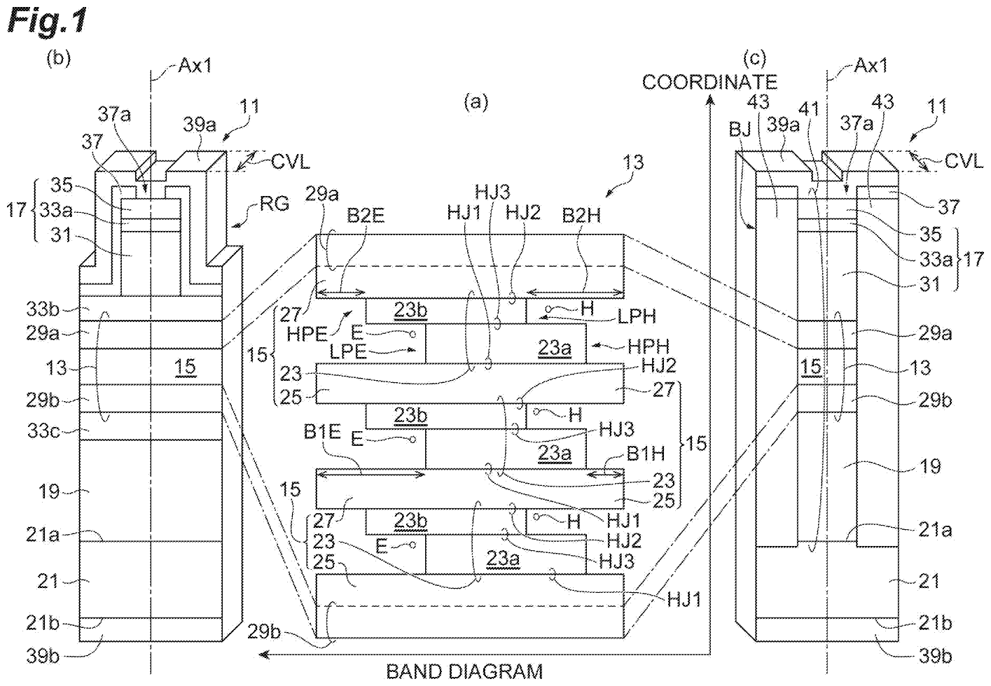

The portion (a) in FIG. 1 is a diagram showing the structure of an active layer of a semiconductor laser according to the present embodiment, and showing potentials of a conduction band and valence band of the active layer. Each of the portions (b) and (c) in FIG. 1 is a diagram showing the semiconductor laser including the active layer shown in the portion (a) in FIG. 1.

A semiconductor laser 11 includes an active layer 13, and the active layer 13 has at least one type II quantum well structure 15. The semiconductor laser 11 further includes a p-type semiconductor region 17 and an n-type semiconductor region 19, and the active layer 13 is provided between the p-type semiconductor region 17 and the n-type semiconductor region 19. The semiconductor laser 11 can further include a support 21, and the p-type semiconductor region 17, the active layer 13, and the n-type semiconductor region 19 are mounted on the semiconductor main surface (referred to as a main surface 21a) of the support 21.

The type II quantum well structure 15 includes a well layer 23 containing a III-V compound semiconductor and a plurality of barrier layers containing a III-V compound semiconductor, and the well layer 23 is provided between these barrier layers. In the type II quantum well structure 15, the plurality of barrier layers include at least one of a first barrier layer 25 and a second barrier layer 27. In this example, the type II quantum well structure 15 includes the first barrier layer 25 and the second barrier layer 27 in addition to the well layer 23. The well layer 23 is provided between the first barrier layer 25 and the second barrier layer 27. The first barrier layer 25 provides respective barriers (B1E and B1H) for electrons E and holes H in the well layer 23. The second barrier layer 27 provides respective barriers (B2E and B2H) for electrons E and holes H in the well layer 23. The III-V compound semiconductor can include, for example, a ternary compound or a quaternary compound.

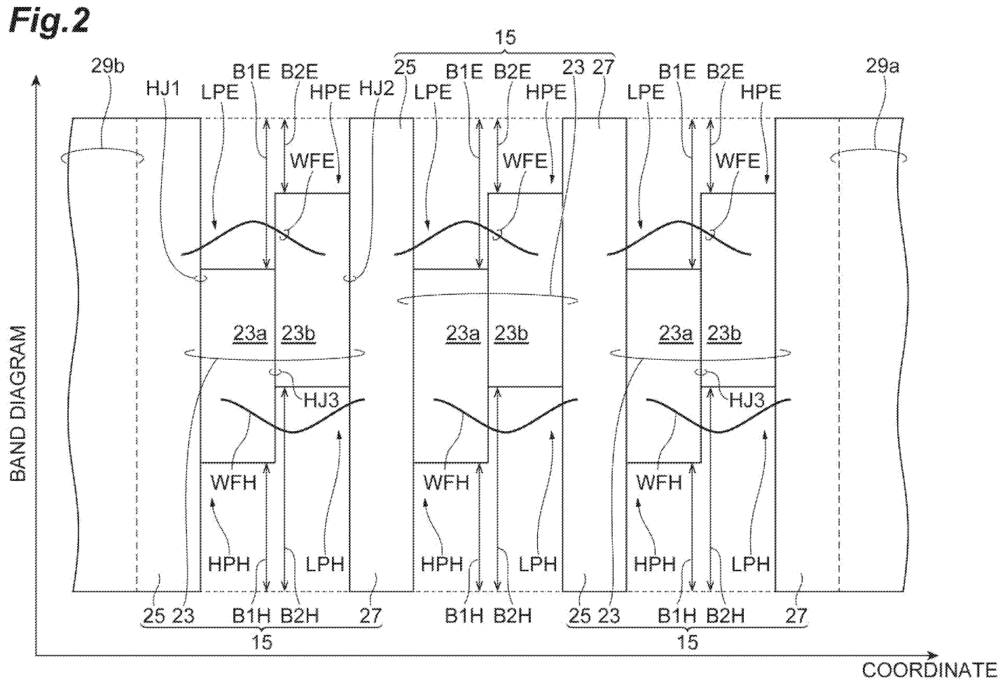

The exemplary active layer 13 is shown in the portion (a) in FIG. 1 and FIG. 2, and the active layer 13 includes three well layers 23. Specifically, each of the well layers 23 includes at least one first region 23a and at least one second region 23b. The first region 23a has a low potential LPE for electrons E in the well layer 23 and a high potential HPH for holes H in the well layer 23. The second region 23b has a high potential HPE for electrons E in the well layer 23 and has a low potential LPH for holes H in the well layer 23. For the electrons E, an energy level of the high potential HPE is higher than that of the low potential LPE. For the holes H, an energy level of the low potential LPH is lower than that of the high potential HPH. The first region 23a and the second region 23b are arranged in a direction of the first axis Ax1 from the first barrier layer 25 to the second barrier layer 27.

In the type II quantum well structure 15 according to this example, a single first region 23a and a single second region 23b can be provided in the well layer 23. In addition, in the well layer 23 including a plurality of first regions 23a and one or more of second regions 23b, for example, two first regions 23a and one second region 23b, the first regions 23a and the second region 23b are alternately arranged in a direction of the first axis Ax1. Alternatively, in the well layer 23 including one or more first regions 23a and a plurality of second regions 23b, for example, one first region 23a and two second regions 23b, the first region 23a and the second regions 23b are alternately arranged in a direction of the first axis Ax1.

FIG. 2 is a diagram showing conduction and valence band potentials of the active layer including three type II quantum well structures 15 and wave functions of electrons and holes in the well layer.

### (First Barrier Layer 25)

The first barrier layer 25 in the well layer 23 forms a type I heterojunction HJ1 with the first region 23a in the well layer 23. The type I heterojunction HJ1 causes a shift of a wave function WFE of electrons E in the first region 23a toward the second region 23b. The wave function WFE provides the low potential LPE for electrons E. This shift allows the shifted wave function WFE to greatly overlap a wave function WFH of holes H in the second region 23b that forms a type II heterojunction HJ3 with the first region 23a.

The first barrier layer 25 provides, at the type I heterointerface, a first electron barrier B1E for the electron E in the conduction band of the first region 23a, and provides a first hole barrier B1H for the hole H in the valence band of the first region 23a. The first electron barrier B1E defines the low potential LPE of the first region 23a, and the first hole barrier B1H defines the high potential HPH of the first region 23a. An absolute value of the first electron barrier B1E is larger than an absolute value of the first hole barrier B1H.

### (Second Barrier Layer 27)

The second barrier layer 27 in the well layer 23 forms a type I heterojunction HJ2 with the second region 23b in the well layer 23. The type I heterojunction HJ2 causes a shift of a wave function WFH of holes H in the second region 23b toward the first region 23a. The wave function WFH provides the low potential LPH for holes H. This shift allows the shifted wave function WFH to greatly overlap a wave function WFE of electrons E in the first region 23a that forms a type II heterojunction HJ3 with the second region 23b.

The second barrier layer 27 provides, at the type I heterointerface, a second electron barrier B2E for the electron E in the conduction band of the second region 23b, and provides a second hole barrier B2H for the hole H in the valence band of the second region 23b. The second electron barrier B2E defines the high potential HPE of the first region 23b, and the second hole barrier B2H defines the low potential LPH of the first region 23b. An absolute value of the second hole barrier B2H is larger than an absolute value of the second electron barrier B2E.

According to the semiconductor laser 11, in the well layer 23 of a certain type II quantum well structure 15, the first region 23a and the second region 23b arranged in a direction from the first barrier layer 25 to the second barrier layer 27 in the type II quantum well structure 15 are provided. The first region 23a provides a low potential LPE for electrons E in the well layer 23 and a high potential HPH for holes H in the well layer 23. The second region 23b provides a high potential HPE for electrons E in the well layer 23 and provides a low potential LPE for holes H in the well layer 23. The arrangement of the first region 23a and the second region 23b provides a wave function WFE of electrons E in the first region 23a with a large probability density of the electrons E, and provides a wave function WFH of holes H in the second region 23b with a large probability density of the holes H. The squared magnitudes of the wave functions WFE and WFH give the probability densities which are proportional to a spatial distribution electrons and holes in the well layer 23. The first barrier layer 25 and the second barrier layer 27 cause the wave function WFE of electrons E and the wave function WFH of holes H in the well layer 23 to be shifted inward.

The first barrier layer 25 provides an asymmetric barrier height (an absolute value of the first electron barrier ME is larger than an absolute value of the second electron barrier B2E) from the first barrier layer 25 for the electrons E in the well layer 23. In addition, the second barrier layer 27 provides an asymmetric barrier height (an absolute value of the second hole barrier B2H is larger than an absolute value of the first hole barrier B1H) from the second barrier layer 27 for the holes H in the well layer 23.

The active layer 13 includes a type I heterointerface and a type II heterointerface in the quantum well structure 15. In the well layer 23, the first region 23a can generate a high potential energy for holes, and the second region 23b can generate a high potential energy for electrons. Using a barrier layer that provides a type I heterointerface for the well layer 23, at least one of the spatial distribution of electrons and the spatial distribution of holes in the well layer 23 containing the type II heterointerface is modified.

The transition of carriers (electrons and/or holes) between the conduction and the valence bands are promoted due to the modification of the spatial distributions of the electrons and the holes. In addition, the introduction of the type II heterointerface between the first region 23a and the second region 23b in the well layer 23 can generate light with a long wavelength (for example, light with a wavelength of 1.2 or more, specifically, in a light emitting element using an InP substrate, light with a wavelength of 2 μm or more, and in a light emitting element using a GaAs substrate, light with a wavelength of 1.2 μm or more). In one example, as shown in FIG. 2, a single first region 23a and a single second region 23b are provided in the well layer 23, and the first region 23a and the second region 23b form a type II heterojunction HJ3 with each other. The first region 23a and the second region 23b form single type I heterojunctions with the first barrier layer 25 and the second barrier layer 27, respectively. The first barrier layer 25 and the second barrier layer 27 cause wave functions of electrons and holes in the first region 23a and the second region 23b to be shifted inward. These shifts allow the shifted wave functions to have a greatly overlapping integration in the vicinity of the single type II heterojunction HJ3 between the first region 23a and the second region 23b.

In another example, in the well layer 23, a single first region 23a and two second regions 23b are provided, and the first region 23a is provided between two second regions 23b to form two type II heterojunctions. One of the two second regions 23b forms a type I heterojunction with the first barrier layer 25, and the other of the two second regions 23b forms a type I heterojunction with the second barrier layer 27. These two type I heterojunctions cause wave functions of carriers in the second region 23b to be shifted, and these shifts allow a largely overlapping integration in the vicinity of respective type II heterojunctions.

In still another example, two first regions 23a and a single second region 23b are provided in the well layer 23, and the second region 23b is provided between the two first regions 23a to form two type II heterojunctions. One of the two first regions 23a forms a type I heterojunction with the first barrier layer 25, and the other of the two first regions 23a forms a type I heterojunction with the second barrier layer 27. These two type I heterojunctions cause wave functions of carriers in the second region 23b to be shifted, and these shifts allow a largely overlapping integration in the vicinity of respective type II heterojunctions.

Specifically, in the active layer 13 having a plurality of type II quantum well structures 15, two adjacent type II quantum well structures 15 can be arranged so that the first barrier layer 25 of one well layer 23 is shared as the second barrier layer 27 of the other well layer 23.

Alternatively, in the active layer 13 having a plurality of type II quantum well structures 15, two adjacent type II quantum well structures 15 can be arranged so that the first barrier layer 25 of one well layer 23 is shared as the first barrier layer 25 of the other well layer 23.

Alternatively, two adjacent type II quantum well structures 15 can be arranged so that the second barrier layer 27 of one well layer 23 is shared as the second barrier layer 27 of the other well layer 23.

As necessary, the semiconductor laser 11 can include optical confinement layers 29a and 29b outside the outmost barrier layers (the first barrier layer 25 and the second barrier layer 27) of the active layer 13, respectively.

Referring to the portions (b) and (c) in FIG. 1, the semiconductor laser 11 can have a ridge structure RG or a buried heterostructure BJ. In addition, the semiconductor laser 11 can be of a Fabry-Perot (FP) type or a distributed feedback (DFB) type. The FP-type semiconductor laser 11 has, for example, a cavity length CVL of about 1 mm.

### (Ridge Structure RG)

The semiconductor laser 11 provides the p-type semiconductor region 17 for the ridge structure RG. Specifically, the p-type semiconductor region 17 includes a p-type cladding layer 31 and a p-type contact layer 35. The n-type semiconductor region 19 includes an n-type cladding layer.

As necessary, the semiconductor laser 11 can include a (p-type semiconductor) first intermediate layer 33a, a (p-type semiconductor) second intermediate layer 33b and/or an (n-type semiconductor) third intermediate layer 33c.

The first intermediate layer 33a is provided between the p-type cladding layer 31 and the p-type contact layer 35. The first intermediate layer 33a has a single composition that provides a band gap between the p-type cladding layer 31 and the p-type contact layer 35 or a III-V compound semiconductor layer having a composition gradient that gradually changes a band gap between the p-type cladding layer 31 and the p-type contact layer 35, and the hetero barrier between these semiconductor layers is reduced.

The second intermediate layer 33b is provided between the active layer 13 (the upper optical confinement layer 29a) and the p-type cladding layer 31. The second intermediate layer 33b has a single composition that provides a band gap between the p-type cladding layer 31 and the upper optical confinement layer 29a or a III-V compound semiconductor layer having a composition gradient that gradually changes a band gap between the p-type cladding layer 31 and the upper optical confinement layer 29a, and the hetero barrier between these semiconductor layers is reduced.

The third intermediate layer 33c is provided between the active layer 13 (the lower optical confinement layer 29b) and the n-type cladding layer 19. The third intermediate layer 33c has a single composition that provides a band gap between the n-type cladding layer 19 and the lower optical confinement layer 29b or a III-V compound semiconductor layer having a composition gradient that gradually changes a band gap between the n-type cladding layer 19 and the lower optical confinement layer 29b, and the hetero barrier between these semiconductor layers is reduced.

The semiconductor laser 11 includes an inorganic insulating film 37 covering the ridge structure RG. The semiconductor laser 11 includes a first electrode 39a and a second electrode 39b, and the first electrode 39a is in contact with the p-type semiconductor region 17 via an opening 37a of the inorganic insulating film 37 positioned on the ridge structure RG, and the second electrode 39b is in contact with a back surface 21b of the support 21.

### (Buried Heterostructure BJ)

The semiconductor laser 11 includes a semiconductor mesa 41 and a semiconductor buried region 43. The semiconductor mesa 41 is buried in the semiconductor buried region 43. The semiconductor mesa 41 includes the p-type semiconductor region 17, the active layer 13, and the n-type semiconductor region 19. The p-type semiconductor region 17 includes the p-type cladding layer 31 and the p-type contact layer 35. The n-type semiconductor region 19 includes an n-type cladding layer.

The semiconductor laser 11 includes the inorganic insulating film 37 covering upper surfaces of the semiconductor mesa 41 and the semiconductor buried region 43. The semiconductor laser 11 includes the first electrode 39a and the second electrode 39b. The first electrode 39a is in contact with the p-type semiconductor region 17 via the opening 37a of the inorganic insulating film 37 positioned on the semiconductor mesa 41, and the second electrode 39b is in contact with the back surface 21b of the support 21.

In the semiconductor laser 11 shown in FIG. 1, the well layer 23, the first barrier layer 25 and the second barrier layer 27 may contain the following materials.

In the well layer 23, the first region 23a includes a first III-V compound semiconductor containing indium as a Group III element and containing arsenic as a Group V element. The first III-V compound semiconductor is, for example, a ternary compound or a quaternary compound, and does not exclude a compound semiconductor having a quinary or higher constituent element.

Specifically, the first region 23a may contain GaInAs. The first region 23a may contain at least one of GaInAsP and AlGaInAs.

In addition, the second region 23b includes a second III-V compound semiconductor containing gallium as a Group III element and containing antimony as a Group V element. The second III-V compound semiconductor may be a ternary compound or a quaternary compound, and does not exclude a compound semiconductor having a quinary or higher constituent element.

Specifically, the second region 23b may contain GaAsSb. The second region 23b may contain at least one of GaInAsSb and AlGaAsSb. The first III-V compound semiconductor is bonded to the second III-V compound semiconductor to form a type II heterointerface.

According to the semiconductor laser 11, a combination of the ternary compound and the quaternary compound of the first III-V compound semiconductor and the ternary compound and the quaternary compound of the second III-V compound semiconductor provide a quantum level at which light can be emitted. These ternary compounds and quaternary compounds enable emission of light with a long wavelength. The ternary compound and the quaternary compound provide a type II band alignment for the well layer 23 including the first region 23a and the second region 23b.

The first region 23a may have a thickness of 1 to 10 nm, and the second region 23b may have a thickness of 1 to 10 nm.

In the type II quantum well structure 15, the first barrier layer 25 includes a third III-V compound semiconductor containing gallium as a Group III element and at least one of arsenic and phosphorus as a Group V element.

In addition, the second barrier layer 27 includes a fourth III-V compound semiconductor containing gallium as Group III element and at least one of arsenic and phosphorus as a Group V element.

According to the semiconductor laser 11, the first barrier layer 25 and the second barrier layer 27 provide barriers for both electrons and holes in the first region 23a and the second region 23b in the well layer 23.

Third III-V compound semiconductor and fourth III-V compound semiconductor: AlGaAs, AlGaInP, GaInP, GaAsP, AlInAs, and AlGaInAs

GaAsP may have a lattice constant smaller than a lattice constant of GaAs, and AlGaInP and GaInP may have a lattice constant smaller than a lattice constant of GaAs.

AlInAs and AlGaInAs may have a lattice constant smaller than a lattice constant of InP.

The first barrier layer 25 may have a thickness of 5 to 50 nm, and the second barrier layer 27 may have a thickness of 5 to 50 nm. The well layer 23 may have a thickness of 2 to 20 nm.

The p-type cladding layer and the n-type cladding layer have a band gap larger than a band gap of the first barrier layer 25 and the second barrier layer 27. The p-type cladding layer and the n-type cladding layer form a junction different from the type II heterojunction, for example, a type I heterojunction with the barrier layers (25 and 27) or the optical confinement layers (29a and 29b). The p-type cladding layer and the n-type cladding layer may contain AlGaAs, AlGaInP, AlInAs, and InP.

The support 21 includes a semiconductor support containing any one of GaAs and InP. According to the semiconductor laser 11, the active layer 13 that enables emission of light with a long wavelength is provided on a semiconductor support containing any one of GaAs and InP. GaAs and InP can provide a wafer with a large diameter.

In the semiconductor laser 11 including a GaAs semiconductor support, at least one of the third III-V compound semiconductor and the fourth III-V compound semiconductor may be a ternary compound containing any one of arsenic and phosphorus as a Group V element. According to the semiconductor laser 11, the barrier layer is provided using a ternary compound containing gallium as a Group III element and one of arsenic and phosphorus as a Group V element. The ternary compound, for example, GaAsP and GaInP, can cancel out some or all of compressive strain in the well layer on the GaAs surface.

The semiconductor laser 11 including a GaAs semiconductor support generates light with a long wavelength (for example, light with a wavelength of 1.2 μm or more).

In the semiconductor laser 11 including an InP semiconductor support, at least one of the third III-V compound semiconductor and the fourth III-V compound semiconductor may further include aluminum as a Group III element.

According to the semiconductor laser 11, the barrier layers (25 and 27) are provided using a ternary compound and a quaternary compound containing at least one of gallium and aluminum as a Group III element and at least one of arsenic and phosphorus as a Group V element. The III-V compound semiconductor, for example AlInAs, AlGaInAs, and GaInAsP, can cancel out some or all of compressive strain in the well layer 23 on the InP surface.

In the semiconductor laser 11 including an InP semiconductor support, one of GaInAs of the first region 23a and GaAsSb of the second region 23b may have a larger lattice constant than InP, and the other of GaInAs of the first region 23a and GaAsSb of the second region 23b may have a smaller lattice constant than InP.

According to the semiconductor laser 11, the first region 23a containing GaInAs and the second region 23b containing GaAsSb can cancel out some or all of stress of the well layer 23 on the InP main surface.

The semiconductor laser 11 including an InP semiconductor support generates light with a long wavelength (for example, light with a wavelength of larger than 2 μm).

### (Typical Ridge Structure of Semiconductor Laser 11)

Inorganic insulating film 37: silicon-based inorganic insulating film such as SiN
p-type semiconductor region 17
p-type contact layer 35: p-type GaAs layer
Second intermediate layer 33b: p-type Al(x)Ga(1−x)As composition gradient layer (x is in a range of 0 or more and 1 or less)
p-type cladding layer 31: p-type AlGaAs, p-type GaInP, p-type AlGaInP
First intermediate layer 33a: Al(y)Ga(1−y)As composition gradient layer (y is in a range of larger than 0 and less than 1)
Upper optical confinement layer and lower optical confinement layer:

### AlGaAs and GaInAsP

Active layer 13
Barrier layer: AlGaAs and GaInAsP
First region 23a/second region 23b of well layer 23: GaInAs/GaAsSb type II heterostructure, GaInAsP/GaAsSb
Number of type II heterojunctions in well layer 23: 1 to 4
Third intermediate layer 33c: Al(z)Ga(1-z)As composition gradient layer (z is in a range of larger than 0 and less than 1)
n-type semiconductor region 19: n-type AlGaAs cladding layer, n-type
GaInP cladding layer, and n-type AlGaInP cladding layer
Support 21: n-type GaAs
Cavity length: 1 mm
Width of semiconductor ridge: 5 μm
Typical ridge structure of semiconductor laser 11 (structure that does not contain Al as a constituent element)
Inorganic insulating film 37: silicon-based inorganic insulating film such as SiN
p-type semiconductor region 17
p-type contact layer 35: p-type GaAs layer
Second intermediate layer 33b: p-type GaInAsP layer
p-type cladding layer 31: p-type GaInP layer
First intermediate layer 33a: GaInAsP layer
Upper optical confinement layer and lower optical confinement layer:

### GaInAsP

Active layer 13
Barrier layer: GaInAsP
First region 23a/second region 23b of well layer 23: GaInAs/GaAsSb
type II heterostructure, GaInAsP/GaAsSb
Number of type II heterojunctions in well layer 23: 1 to 4
Third intermediate layer 33c: GaInAsP layer
n-type semiconductor region 19: n-type GaInP cladding layer
Support 21: n-type GaAs
Cavity length: 1 mm
Width of semiconductor ridge: 5 μm

### (Typical Buried Heterostructure of Semiconductor Laser 11)

Inorganic insulating film 37: silicon-based inorganic insulating film such as SiN
p-type semiconductor region 17
p-type contact layer 35: p-type GaInAs layer
Second intermediate layer 33b: p-type AlGaInAs layer
p-type cladding layer 31: p-type AlinAs layer
Upper optical confinement layer and lower optical confinement layer: AlGaInAs
Active layer 13
Barrier layer: AlGaInAs
First region 23a/second region 23b of well layer 23: GaInAs/GaAsSb
type II hetero structure, GaInAsP/GaAsSb
Number of type II heterojunctions in well layer 23: 1 to 4
n-type semiconductor region 19: n-type AlInAs cladding layer
Support 21: n-type InP
Semiconductor buried region 43: semi-insulating InP current blocking layer
Cavity length: 500 μm
Width of semiconductor mesa 41: 3 μm

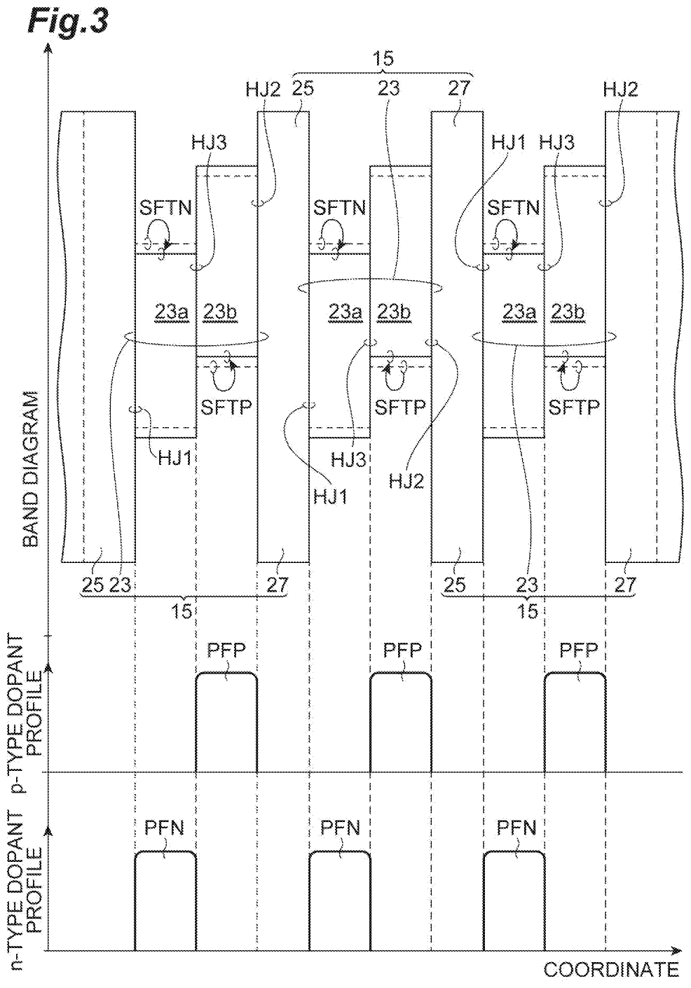

FIG. 3 is a diagram showing profiles of selectively added dopant in the type II quantum well structure. The profiles shown in FIG. 3 show selective dopant addition provided for both the first region 23a and the second region 23b. Alternatively, selective dopant addition is provided for at least one of the first region 23a and the second region 23b. Selective dopant addition may be provided for the first region 23a or selective dopant addition may be provided for the second region 23b.

As described above, the first region 23a has the low potential LPE that is lower than the high potential HPE of the second region 23b and is applied to electrons E in the well layer 23 and has the high potential HPH that is higher than the low potential LPH of the second region 23b and is applied to holes H in the well layer 23. When an n-type dopant is added to the first region 23a, the n-type dopant may be provided for some or all of the first region 23a. Addition of the n-type dopant lowers the low potential LPE like SFTN shown in FIG. 3 to deepen the well. The deep well lowers the quantum level in the well of the conduction band in the type II quantum well structure 15, and reduces a difference between two energy levels that contribute to optical transition in the type II quantum well structure 15. Addition of the n-type dopant shifts the level for optical transition in the type II quantum well structure 15 toward a longer wavelength, and a small level difference enables emission of light with a long wavelength.

In this example, an n-type dopant profile PFN in which an n-type dopant is added to the entire first region 23a is shown. The n-type dopant includes silicon.

Concentration of n-type dopant: for example, 10¹⁷ to 10¹⁹ cm⁻³ for InGaAs

In addition, as described above, the second region 23b has high potential HPE that is higher than the low potential LPE of the first region 23a and is applied to electrons E in the well layer 23, and has a low potential LPH that is lower than the high potential HPH of the first region 23a and is applied to holes in the well layer 23. When a p-type dopant is added to the second region 23b, the p-type dopant may be provided for some or all of the second region 23b. Addition of the p-type dopant lowers the low potential LPP like SFTP shown in FIG. 3 to deepen the well. The deep well lowers the quantum level in the well of the valence band in the type II quantum well structure 15, and reduces a difference between two energy levels contributing to optical transition in the type II quantum well structure 15. Addition of the p-type dopant shifts the level for optical transition in the type II quantum well structure 15 toward a longer wavelength, and a small level difference enables emission of light with a long wavelength.

In this example, a p-type dopant profile PFP in which a p-type dopant is added to the entire second region 23b is shown. The p-type dopant includes zinc, carbon, and beryllium.

Concentration of p-type dopant: for example, 10¹⁷ to 10¹⁹ cm⁻³ for GaAsSb.

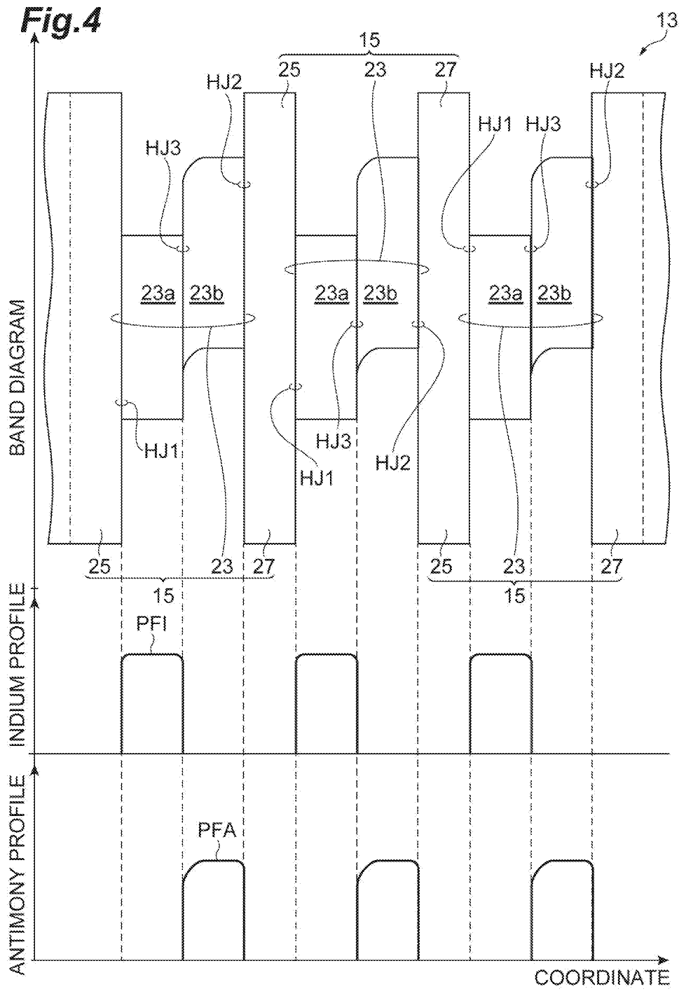

FIG. 4 is a diagram showing profiles of indium and antimony in the type II quantum well structure.

The first III-V compound semiconductor in the first region 23a contains indium (indium profile PFI) as a Group III element and containing arsenic as a Group V element. In this example, the first III-V compound semiconductor does not contain antimony as a Group V element except for contamination. Specifically, the first III-V compound semiconductor is a ternary compound or quaternary compound containing indium and gallium as Group III elements and arsenic as a Group V element.

The second III-V compound semiconductor of the second region 23b contains gallium as a Group III element and containing antimony (antimony profile PFA) as a Group V element. The second III-V compound semiconductor does not contain indium as a Group III element except for contamination. Specifically, the second III-V compound semiconductor is a ternary compound or quaternary compound containing gallium as a Group III element and containing antimony and arsenic as Group V elements.

Specifically, when the concentration of the n-type dopant in GaAs increases from 1×10¹⁵ cm⁻³ to 1×10¹⁸ cm⁻³, the level of the conduction band of GaAs causes a shift of 0.18 eV based on the Fermi level. When this energy shift is converted into the wavelength, the effective wavelength difference is 0.17 μm (for example, shift from 1 μm to 1.17 μm).

When one or two constituent elements are added in addition to gallium as a Group III element and antimony as a Group V element, the lattice constant of the resulting ternary compound or quaternary compound can be made smaller than the lattice constant of the binary gallium antimony and close to the lattice constant of GaAs and InP. When one or two constituent elements are added in addition to indium as a Group III element and arsenic as a Group V element, the lattice constant of the resulting ternary compound or quaternary compound can be made smaller than the lattice constant of binary indium arsenic and close to the lattice constants of GaAs and InP.

According to the following production method including main steps, the semiconductor laser 11 can be produced. First, an epitaxial substrate for the semiconductor laser 11 is produced by growing a stack of semiconductor layers on a semiconductor substrate. The type II quantum well structure and the cladding layer are grown, for example, according to metal organic chemical vapor deposition (MOCVD) or molecular beam epitaxy (MBE). In order to grow a Si-doped GaInAs and updoped GaAsSb quantum well structure, trimethylgallium (TMGa), trimethylindium (TMIn), tertiary butylarsine (IBAs), and trimethylantimony (TMSb) are used as raw materials for gallium (Ga), indium (In), arsenic (As) and antimony (Sb). The n-type dopant source, for example, a Si dopant source, contains silane (SiH₄). The carrier gas includes, for example, hydrogen. These raw materials and the dopant gas are supplied into a reaction furnace, and a stack of semiconductor layers is epitaxially grown on an InP substrate in the reaction furnace. Specifically, TMGa, TMIn and TBAs are supplied at a gas phase ratio at which the semiconductor product is lattice-matched to the InP substrate. At the same time, a SiH₄ gas is supplied to the reaction furnace at a gas phase ratio at which the donor concentration is 1×10¹⁸ cm⁻³, and thus a Si-doped GaInAs layer is grown by selective doping. In the subsequent growth of a GaAsSb layer, supply of TMGa, TMIn, TBAs and SiH₄ is stopped. Next, TMGa, TBAs and TMSb are supplied at a gas phase ratio at which the semiconductor product is lattice-matched to the InP substrate. The well layer can be grown according to this sequence. A type II multiple quantum well structure can be formed by repeating growth of the well layer and the barrier layer.

Next, the epitaxial substrate produced in this manner is subjected to photolithography, etching (as necessary, re-growing), and metallization. The semiconductor laser 11 having a ridge structure (or a buried heterostructure when re-grown) having a type II multiple quantum well structure are obtained.

While principles of the present invention have been illustrated and described in the preferred embodiments, it will be understood by those skilled in the art that the present invention can be modified in arrangement and details without departing from such principles. The present invention is not limited to the specific configuration disclosed in the present embodiment. Therefore, the inventors claim all modifications and alternations from the scope of claims and the spirit thereof.

What is claimed is:

1. A semiconductor laser, comprising:
a p-type semiconductor region;
an n-type semiconductor region; and
an active layer which is provided between the p-type semiconductor region and the n-type semiconductor region, and has a type II quantum well structure,
wherein the type II quantum well structure includes
a well layer made of a III-V compound semiconductor and
a plurality of barrier layers that provide respective barriers for electrons and holes in the well layer,
wherein, in the type II quantum well structure, the well layer is provided between the barrier layers,
wherein the well layer includes a first region and a second region, the first region having a low potential for electrons in the well layer and a high potential for holes in the well layer, the second region having a high potential for electrons in the well layer and a low potential for holes in the well layer, the high potential of the second region being higher than the low potential of the first region, the low potential of the second region being lower than the high potential of the first region, and
wherein the first region and the second region of the well layer are arranged in a direction from one of the barrier layers to another of the barrier layers.

2. The semiconductor laser according to claim 1,
wherein the first region includes a first III-V compound semiconductor containing indium as a Group III element and containing arsenic as a Group V element, and the first III-V compound semiconductor is a ternary compound or a quaternary compound,
wherein the second region includes a second III-V compound semiconductor containing gallium as a Group III element and containing antimony as a Group V element, and the second III-V compound semiconductor is a ternary compound or a quaternary compound.

3. The semiconductor laser according to claim 1,
wherein the first region contains GaInAs, and
wherein the second region contains GaAsSb.

4. The semiconductor laser according to claim 1,
wherein the first region has a part containing an n-type dopant.

5. The semiconductor laser according to claim 1,
wherein the second region has a part containing a p-type dopant.

6. A semiconductor laser, comprising:
a p-type semiconductor region;
an n-type semiconductor region; and
an active layer which is provided between the p-type semiconductor region and the n-type semiconductor region and has a type II quantum well structure,
wherein the type II quantum well structure includes
a plurality of well layers containing a III-V compound semiconductor, and
a plurality of barrier layers that provide respective barriers for electrons and holes in each of the well layers,
wherein the well layers and the barrier layers are alternately arranged so that each of the barrier layers is provided between the well layers,
wherein each of the well layers includes at least one first region and at least one second region,
wherein the at least one first region and the at least one second region of each of the well layers are alternately arranged in a direction from one of the barrier layers to another of the barrier layers,
wherein each of the at least one first region forms a type II heterojunction with at least one of the at least one second region, and
wherein at least one of the at least one first region and the at least one second region has a part containing a dopant.

7. The semiconductor laser according to claim 6,
wherein the at least one first region has a low potential for electrons in the well layer and has a high potential for holes in the well layer, and
wherein the at least one first region has a part containing an n-type dopant.

8. The semiconductor laser according to claim 7,
wherein the at least one second region has a high potential for electrons in the well layer and has a low potential for holes in the well layer, and
wherein the at least one second region has a part containing a p-type dopant.
